(19) United States
(12) Patent Application Publication
(10) Pub. No.: US 2003/0108752 A1
(43) Pub. Date: Jun. 12, 2003

(54) Substrate body coated with multiple layers and method for the production thereof

(76) Inventors: Udo König, Essen (DE); Ralf Tabersky, Bottrop (DE); Hendrikus Van Den Berg, Venlo-Blerick (NL)

Correspondence Address: THE FIRM OF KARL F ROSS, 5676 RIVERDALE AVENUE, PO BOX 900, RIVERDALE (BRONX), NY, 10471-0900, US

(21) Appl. No.: 10/257,086

(22) PCT Filed: Mar. 8, 2001
(86) PCT No.: PCT/DE01/00903

(30) Foreign Application Priority Data
Apr. 6, 2000 (DE) 100169589

(51) Int. Cl. C23C 16/00; B05D 1/36; B32B 15/04

(52) U.S. Cl. 428/469; 427/402; 427/255.28; 427/569; 428/472; 428/698; 428/701

(57) ABSTRACT

The invention relates to a method for producing a wearing protection layer according to a CVD method. Said protection layer consists of a plurality of thin individual layers having a layer thickness of 1 to 100 nm respectively. The respective individual layers are successively deposited on a substrate body. The invention also relates to a correspondingly coated substrate body. According to the invention, the CVD method which is activated by means of a glow discharge plasma is carried out under a pressure of 50 Pa to 1,000 Pa and at a temperature of not more than 750 ° C. in such a way that the voltage for producing the glow discharge is switched off while the gas composition is changed for preparing the deposition of the next individual layer or that a gas or a gas mixture of argon, hydrogen and/or nitrogen is led into the coating container at an essentially constantly high temperature and the glow discharge is maintained by applying a voltage of 200 V to 1,000 V over a period that is shorter than the period of coating of the last individual layer.

The invention relates to a method of making a wear-protective layer from a multiplicity of thin individual layers with respective layer thicknesses of 1 to 100 nm and of a total thickness of 0.5 to 20 μm by means of a CVD process in which the respective individual layers are successively deposited one after the other upon a substrate body, especially to produce a cutting insert comprised of a hard metal, cermet, ceramic or a metal or steel alloy substrate body with the wear-protective layer.

The invention relates further to a composite material, especially a tool, comprised of a substrate body of a hard metal, a cermet, a ceramic or a metal or a steel alloy and a wear-protective layer comprised of a multiplicity of individual layers with a thickness between 1 to 100 nm, preferably 5 to 50 nm and deposited thereon.

From DE 29 17 348, a wear-resistant composite body for machining metallic and nonmetallic workpieces is known which is comprised of a base body as well as a multiplicity of binder metal-free hard material layers with respective thicknesses of 1 to 50 μm and of different compositions. One of the hard material layers should have a thickness of 3 to 15 μm and be composed of very many thin individual layers with a thickness each of 0.02 to 0.2 μm, whereby the hard material composition of each individual layer difference from the hard material composition of the two neighboring individual layers. For example, alternations of titanium carbide or titanium nitride or titanium carbonitride on the one hand and aluminum oxide or zirconium oxide on the other for the alternating individual layers can be provided. Each of the alternating individual layers of titanium nitride and aluminum oxide in the composition or of titanium carbide or titanium nitride or titanium carbonitride on the one hand and aluminum oxide or zirconium oxide on the other and an outer aluminum oxide layer for respective wear-protective layers are given as examples. To apply the coatings a CVD process of conventional type is used in which the coating temperature was 1000° C. or more. In the CVD process which was used, furnace atmosphere pressures of 50 mbar were employed. In practice, the production of the mentioned multilayer coatings by means of the described CVD process is very difficult and impossible for large volume production runs. In order to produce a multilayer coating of TiN and Al₂O₃, for example, one must replace a gas temperature comprised of TiCl₄, N₂ and H₂ with another of the gases AlCl₃, CO₂ and H₂ in rapid changeover. Aside from this, in the described example, the previously applied TiN individual layer oxidizes. With the given CVD process that is carried out at 1000° C. and atmospheric pressures of 5000 Pa, the layer growth speed is not only very rapid, which leads to the deposition of thin individual layers but because of point-like differences in the layer growth conditions, the layer thickness distribution is nonuniform. It should be noted also that in the respective edge zones of the individual layers, mixed phases arise during alternations in gas composition so that components for a previously deposited individual layer unavoidably also contain components for the next individual layer to be produced.

In practice moreover efforts have been made to overcome those drawbacks through the provision of wear-protective coatings which are comprised of multiple individual layers by application of a PVD process. Thus in EP 0 197 185 B1, a process is described for producing multilayer hard material protective layers and comprised of different hard material phases for metallic, highly stressed surfaces and other substrates whereby the thickness of the overall protective layer lies in the range of 0.1 to 10 μm both on the metallic surfaces and also under one another there are firmly adherent individual coatings or layers or finely dispersed hard material particle mixtures with individual layer thicknesses or particle sizes of such individual layer thicknesses of the particle sizes in the range of 0.5 nm to 40 nm. In the case of 0.5 nm thick individual layers or particle sizes, the total number of the individual layers or their inner phase boundaries is between 100 to 20000. With reference to the crystal lattice, coherent or partly coherent phase boundaries are provided whereby the individual coatings or layers or the hard material particles are deposited by cathodic sputtering or via another PVD method on the cathodic surface or on the substrate whereby either the surface to be coated is moved relative to at least two sputtering cathodes of different hard materials during the total coating process or the coating of the surface or the substrate is carried out with the aid of a cathode comprised of at least two mutually coherent or partly coherent phase boundaries forming the hard material. For the described version the method can use cathodes of TiC and TiB₂ or TiN and TiB₂ or TiC and TiN and TiB₂ or of pure metal.

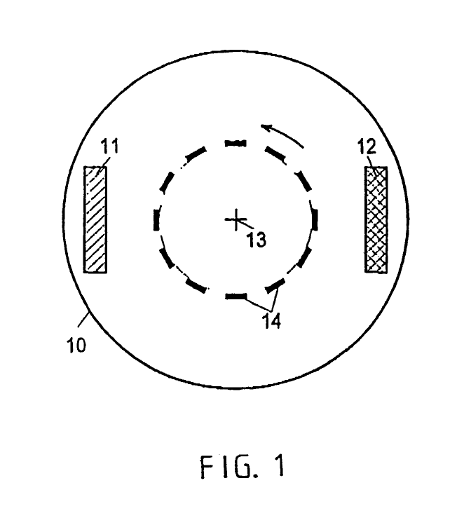

An apparatus suitable for carrying out such a coating process is schematically illustrated in FIG. 1.

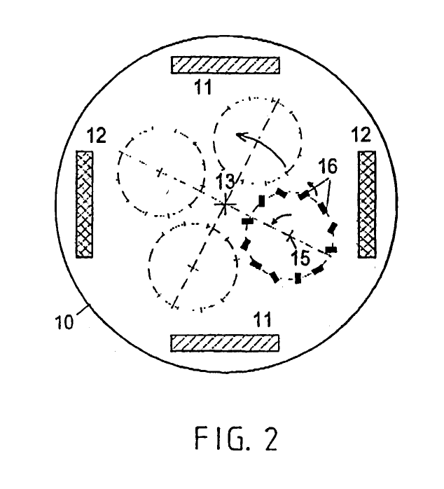

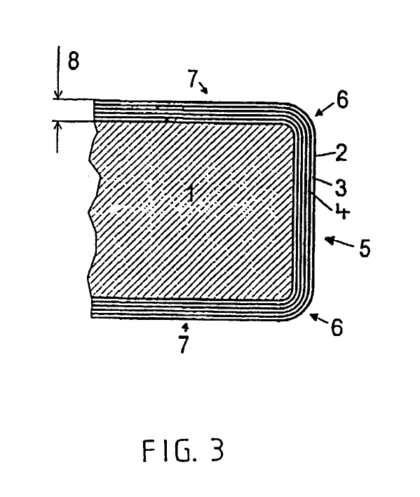

In an autoclave 10 at diametrically opposite sides, a first target 11 composed of titanium and a second target 12 composed of aluminum are disposed. By reactive sputtering in combination with the N₂ atmosphere established in the autoclave, layer sequences of TiN—AlN can be deposited on the substrate bodies 14 which are movable about the axis 13 of rotation by means of a suitable rotation device. With such an arrangement, the substrates 4 can however only be coated from one side, namely, that which is turned toward the targets 11 and 12. To carry out a multiside coating and to ensure high productivity, planet-like holders according to FIG. 2 are required in which the substrate bodies 16 arranged on a satellite frame are movable about one axis of rotation 15 on the one side and the entire satellite frame is moved additionally about the rotation axis 13. Additionally each substrate body 16 can also be rotated about its own axis whereby in the case illustrated in FIG. 2, four targets of the aforedescribed type are used. Indeed with the arrangement according to FIG. 2 which is however very expensive from an apparatus point of view, it is in principle possible to carry out a multisided coating of the substrate bodies which yet allows, because of the single gas atmosphere, for example of nitrogen, with use of titanium and aluminum targets for instance, only TiN—AlN deposits to be obtained. This system also results in mixed phases in the individual layers which thus contain the nitride of aluminum as well as of titanium and which cannot be avoided so that the desired advantages of a wear-protective layer whose individual layers are namely distinct from one another with respect to composition, cannot be achieved. In one and the same autoclave, i.e. in a continuous PVD process, multilayer coatings with alternating individual layers of TiN and Al₂O₃ cannot be produced since that requires in the cadence of passage of the substrate ahead of the different metal targets a changeover of the reactive gas, namely between nitrogen on the one hand and oxygen on the other. In addition with such PVD coatings, it is a drawback that individual layers with larger layer thicknesses individual to them cannot be produced in practice. Should the laminar coating of the individual layers have to be uniform with respect to layer thickness distribution, as will be later described in connection with FIG. 3, the aforedescribed PVD coating process and the subsequent treatment is unsuitable. It has been found also in EP 0 197 185 B1, column 3, lines 44 to 47, that in a deposition in which the samples are arranged on a turntable and continuously moved beneath two different cathodes, namely of TiC and TiB₂, mixed coatings can arise by sputtering.

DE 195 03 070 C1 describes a wear-protective coating composed of a multiplicity of individual layers which has a first individual layer applied to a metallic hard material which is directly applied to the substrate and further individual layers which are coated onto the first layer in a periodically repeated sequence from a metallic hard material and another hard material. The mentioned other hard material should be a covalent hard material. The individual layers are comprised of a periodically repeated sequence of a composite of three individual layers whereby the composite of two individual layers comprises two different metallic materials and one individual layer of the covalent hard material for which as a special example a composite of two individual layers of titanium nitride and titanium carbide and a further individual layer of covalent hard material boron carbide is given. To produce such a layer sequence of individual layers, in a PVD process, a plurality of cathodes is reactively or nonreactively sputtered from the respective desired layer material onto the substrate, whereby the substrate is periodically conveyed under the cathode somewhat as upon a turntable.

EP 0 701 982 A1 relates to a wear-protective layer of a multiplicity of individual layers which each have a thickness of 1 nm to 100 nm. The individual layers of at least two compounds comprised substantially of carbides, nitrides, carbonitrides or oxides of at least one of the elements of groups IVB to VIB elements of the periodic system, Al, Si and B. To produce such layer sequences, an ion plating should be used with a vacuum arc discharge. For this purpose a multiplicity of targets are arranged in a vacuum chamber past which substrate bodies arranged on a turntable are rotated. To the extent that a CVD coating technique is referred to in this reference, it is understood to be a conventional CVD process for comparative purposes with which 0.5 μm layers are deposited.

EP 0 592 986 B1 describes a wear-resistant element of a carrier material and an ultrathin film laminate applied thereon and which has at least one nitride or carbonitride of at least one element that is selected from a group which is comprised of the elements of groups IVB, VB and VIB of the periodic system as well as Al and B, whereby the nitrides or carbonitrides have a cubic crystal structure and mainly metal binding characteristics, as well as at least one compound which at standard temperature and standard pressure and in an equilibrium state has another crystal structure than the cubic crystal structure and which has mainly covalent bonding characteristics at least one nitride or carbonitride and the last-mentioned compounds should be applied alternately whereby each individual layer has a thickness of 0.2 to 20 nm and the laminate as a whole has a cubic crystalline x-ray diffraction diagram. The relevant laminate coatings should also be applied by means of a PVD process only and comparatively are, for example, individual layers of titanium nitride, aluminum oxide and titanium carbide with layer thicknesses of 0.5 μm or more mentioned. The above described coatings are treated correspondingly to those of EP 0 709 483 A2.

The wear-resistant coating for a cutting tool having a first layer of TiC with a thickness of 1 μm on the surface of the cutting tool and 100 alternating layers of equal thickness of the compounds TiN and ZrN or a 5 μm thickness overcoat comprised of three identically thick layers of (Ti,Zr)(C,N),(TiZr)C and (TiZr)N or a 5 μm thick overcoat of 1500 equal thickness mutually alternating layers of TaB₂, NbB₂, MoB₂ or a 5 μm thick overcoat of 600 mutually alternating layers of Ta₅Si₃Nb₃Si₃ which has a tetragonal crystal lattice of the Cr₅B₃ type, each with a layer thickness ratio of 1:2 or a 5 μm thick overcoat of 200 mutually alternating layers of the compounds TiO, ZrO with cubic lattice and a layer thickness ratio respectively of 1:3 is described in DE 35 39 729 C2. The application of the coating by a PVD process is proposed.

Laminate layers with a thickness of 1 to 100 nm which are applied by means of PVD process are described also in EP 0 885 984 A2.

Finally WO 98/48072 and WO 98/44163 deal with thin individual layers with a maximum thickness of 30 nm or 100 nm which are supposed to be applied basically by CVD or PVD process although in the examples the PVD technique is exclusively referred to.

Using the previously described state of the art as a basis, it is an object of the present invention to provide a CVD coating process which can, in an economical manner, apply a multiplicity of individual layers of different hard material compositions to a substrate body, whereby the formation of mixed phases in the transition regions form individual layer to individual layer is at least largely avoided. It is also an object of the present invention to provide correspondingly improved composite bodies and their compositions and especially such as are suitable for use as cutting tools for machining.

The aforementioned objects are achieved by means of the method described in claim 1 which is characterized by a CVD process carried out at a pressure of 50 Pa to 1000 Pa and a temperature of a maximum of 750° C. activated by a glow discharge plasma. Under these conditions there is surprisingly even in large reactors the possibility of replacing completely the gas mixture required for the CVD process in a short time, that is in seconds. As substrate bodies, especially for cutting inserts, hard metals, cermets, ceramics or also metallic substrates like steel-based bodies, can be used. As the hard materials, all of those basically known from the state of the art can be used as can those described in the aforementioned documents and the described compounds and the gas mixtures suitable for their deposition. Such compounds are especially carbides, nitrides, carbonitrides of the transition metals titanium, zirconium, hafnium, vanadium, niobium, tantalum, chromium, molybdenum and tungsten (elements of groups IVB to VIB of the periodic system).

Moreover, contemplated also are especially the outer wear-resistant individual layers aluminum oxide or zirconium oxide, aluminum nitride and boron nitride. For a coating which is to comprise a plurality of individual layers with alternating compositions, for example of titanium nitride and aluminum oxide, because of the relatively low coating temperature, the danger of an oxidation by oxygen-containing gases as can be undesirable for example with a TiN layer is excluded.

An especially sharp interface between two individual layers of different compositions is obtained when the glow discharge plasma supporting the CVD reaction is cut off prior to the gas replacement, that is at the end of the coating of the first layer, and only turned on again after the gas replacement in the coating reactor. Surprisingly in spite of the process interruption, the individual layers adhere well to one another even in the cases in which the materials are not miscible in thermal equilibrium as, for example, is the case with a multilayer coating of Al₂O₃ and TiN. In the use of the CVD process, the layer thicknesses are uniform on all sides by contrast with the PVD process. Advantageously, the substrate body or the substrate body already coated with individual layers are not moved during the coating or further coating. Because of the unhindered flow around the bodies to be coated of the process gases admitted to the reactor, the multilayer coating has a laminar structure and is laterally continuous over the entire free area of the substrate body.

Alternatively the objects are achieved by the method described in claim 2.

Here, according to the invention, each of the individual layers is applied by means of a glow discharge plasma activated CVD process at a pressure of 50 to 1000 Pa and a temperature of a maximum of 750° C. Between the individual coating processes for the application of the individual layer, a gas or gas mixture of argon, hydrogen and/or nitrogen is fed in at a pressure of 50 Pa to 1000 Pa into the coating vessel at a substantially uniform elevated temperature and a glow discharge is maintained at the substrate body or partially coated substrate body by the application of a voltage of 200 to 1000 V for a duration which is shorter than the duration of the coating of the individual layer, preferably a maximum of half as long. Basically DE 44 17 729 A1 has already suggested maintaining the glow discharge in a nonreactive gas atmosphere, but only in conjunction with the application of relatively thick layers, with a thickness of 200 nm to 400 nm. The plasma treatment between the individual coating procedures results in numerous defect locations in the otherwise smooth crystallite surfaces with fewer active growth locations in spite of the “attenuation” resulting from the plasma treatment of the previously deposited layer, there are no adhesion problems in the application of the next layer. The lattice structure of the deposited individual layers is as fine-grained as can be achieved with a CVD process at coating temperatures about 1000° C. Further developments of the invention are described in the dependent claims.

Thus by means of the aforedescribed process variants, individual layers can be deposited which each have a different composition from the next individual layer, as well as such multilayer coatings as may have two neighboring individual layers of the same composition.

Advantageously, two neighboring individual layers can be deposited of hard material which are not mutually miscible or alloyable in thermal equilibrium.

Preferably the hard material from which the individual layers are constituted is a compound of at least two components of which the first is at least one element of a group IVB to VIB element of the periodic system or contains Al, Si, C or B and the second, different from the first is at least one of the elements from the group of elements B, C, N, O and S. According to a special feature of the invention, at least a part of the wear protective layer is an alternating sequence of individual layers of Al₂O₃, ZrO₂, AlN BN or B(C,N) on the one hand a nitride or carbonitride of the form (Cₓ,N₁₋ₓ) with 0≦1 of the elements Ti, Zr and Hf on the other hand. As examples applicable here are mutlilayer coatings of A₂O₃ and TiN specifically mentioned. Advantageously, however, also coatings are possible of the type in which there is an alternating sequence of individual layers deposited from TiN and Ti (C,N).

Within the framework of the present invention it is also possible to deposit additionally at least one intervening layer with a thickness of 5 to 50 nm which is comprised of at least one of the elements or compounds of at least two of the elements, C, N, Mo, W, Ti, Al and/or ZrO₂, Si or B as further phases. Especially suitable are here intermediate layers of carbon, carbon-nitrogen compounds, metallic layers of only one metal or also TiAl layers as well as layers in which zirconium dioxide, silicon and boron are incorporated as additives. The method of the invention can be used in such manner that the layer composition has a periodic repetition of the successive individual layers or a nonperiodic sequence. If one uses as the hard material for the individual layers for example three compositions A, B and C, a periodic deposition of optionally as many individual layers as desired of the type A, B, C, A, B, C, . . . can be provided as an example of a periodic sequence of coatings of the form A, B, C, B, A, C, A, C, B . . . can be an example of a nonperiodic sequence as desired. Within the framework of the present invention, individual layers and also possible intermediate layers with the same thickness or different thicknesses can be provided.

According to the invention, the object mentioned at the outset can be achieved with a composite material, especially a tool for machining, which is comprised of a hard metal, a cermet, a ceramic or a metallic body constituting a substrate body and on which is deposited, from a multiplicity of individual layers, a thickness between 1 to 100 nm, preferably 5 to 50 nm of a wear-protective layer according to claim 10. The individual layers are characterized in that they each can be applied by means of a glow discharge plasma activated CVD process at a pressure of 50 Pa to 100 Pa and a temperature of a maximum of 750° C. whereby between two coating processes, for the preparation for depositing the next individual layer, either the voltage for producing the glow discharge is shut off with gas replacement or a gas or a gas mixture of argon, hydrogen and/or nitrogen is introduced into the coating vessel at a pressure of 50 Pa to 1000 Pa and the glow discharge at the substrate body or partially coated substrate body is maintained by applying a voltage of 200 to 1000 volts for a time period which is shorter than the duration of coating of the last individual layer, preferably a maximum of half as long. In this composite body two or more successive individual layers preferably have different compositions. Advantageously, at least two of the individual layers preferably have different compositions. Advantageously, at least two of the individual layers are composed of hard material as has already been indicated previously. It is also possible for at least one of the hard material individual layers to be constituted of a metal carbonitride compound or a metal nitride compound of the composition (M₁M₂) (Cₓ,N_{y}) where M₁ and M₂ are different metals which stem from the group preferably of Ti, Zr, Hf, V, Nb and/or Ta and wherein 0≦x≦1. Suitable possible material combinations are described in WO 97/07160 to which reference is made with respect to the layer composition.

Further advantages and an embodiment example are illustrated schematically in FIG. 3 which shows a partial section through a cutting plate for turning.

The turning cutting plate has a replaceable cutting insert which is basically known from the state of the art has as functional surfaces respective diametrically opposite rake surfaces 7, clearance surfaces 5 and respective rounded cutting edges 6 between the clearance surfaces and the rake surfaces. The cutting insert illustrated in FIG. 3 is comprised of a substrate body 1 which is provided with a wear-protective layer 8 consisting of a multiplicity of at least two individual layers 2, 3 which differ in composition and optionally with an intervening layer or a further individual layer 4 differing as to composition. Each of the individual layers is preferably between 5 and 50 nm thick. The total thickness of the layers corresponds to the wear-protective layer thickness which lies between 0.5 μm and 20 μm.

As to a concrete embodiment, the wear-protective layer comprised of multiple individual layers 2, 3 will be described. The substrate body 1, for example, comprised of a hard metal or ceramic, is cleaned before coating in an ultrasonic bath. A further cleaning is effected by ion etching in a receiver of the plasma reactor in a hydrogen/argon plasma, generated by directed current discharge with pulse sequences at process pressures of 100 to 300 Pa. The heating of the substrate to the coating temperature is supported by an external heating source.

In a first embodiment at a temperature of 6200° C. alternating flows of gas mixtures for depositing titanium nitride and aluminum oxide are admitted to the reactor vessel. The respective process parameters are visible from the following Table 1:

TABLE 1

| | | Titanium Nitride | | Aluminum Oxide | |
|---|---|---|---|---|---|
| Temperature (° C.) | | 620 | | 620 | |
| Pressure (Pa) | | 280 | | 280 | |
| Pulse voltage (V) | | 480 | | 440 | |
| Pulse Duration (μs) | | 50 | | 20 | |
| Pulse Interval (μs) | | 80 | | 10 | |
| Plasma Shutoff for Gas | | 5 | | 5 | |
| Replacement (s) | | | | | |
| Deposition Time of Individual | | 300 | | 300 | |
| Layers (s) | | | | | |
| No. of Individual Layers | | 19 | | 18 | |
| Gas Mixture | (Vol. -%) | TiCl₄ | 0.9% | AlCl₃ | 1.2% |
| | | N₂ | 11% | CO₂ | 3% |
| | | Ar | 13% | Ar | 23% |
| | | H₂ | Remainder | H₂ | Remainder |

After 188 minutes, a total thickness of 1.7 μm of 19 individual layers of titanium nitride and 18 individual layers of aluminum oxide constitute the coating. The respective individual layers of the mentioned substances were of the same thickness, namely 47 nm. Each individual layer was sharply delimited from the adjacent individual layer in that mixed phases in the transition regions were not detectable. The deposited were protective coatings at a Vickers hardness of 2600 HV 0.05.

In a further second embodiment the individual layers were comprised of TiN and AlN. In the example, by contrast with the previous example, 901 individual layers were deposited. The settings can be deduced from the subsequent Table 2.

TABLE 2

| | | Titanium Nitride | | Aluminum Nitride | |
|---|---|---|---|---|---|
| Temperature (° C.) | | 600 | | 600 | |
| Pressure (Pa) | | 260 | | 260 | |
| Pulse Voltage (V) | | 480 | | 390 | |
| Pulse Duration (μs) | | 50 | | 50 | |
| Pulse Interval (μs) | | 80 | | 80 | |
| Plasma Shutoff for Gas | | 2 | | 2 | |
| Replacement (s) | | | | | |
| Deposition Time of | | 20 | | 20 | |
| Individual Layers (s) | | | | | |
| No. of Individual Layers | | 451 | | 450 | |
| Gas Mixture | (Vol. -%) | TiCl₄ | 0.9% | AlCl₃ | 1% |
| | | N₂ | 11% | CO₂ | 19% |
| | | Ar | 13% | Ar | 11% |
| | | H₂ | Remainder | H₂ | Remainder |

According to the invention, in the changeover of the reaction gas necessary for the deposition of the aforementioned material, the glow discharge was shut down each time for 2 seconds. After the deposition of the 901 individual layers, a 4.5 μm thick layer was produced. During the previous example each individual layer had a thickness of 47 nm and the individual layer thicknesses of the second example could no longer be resolved by an optical microscope in the coating of this second embodiment. The average chemical composition of the overall wear-protective layer was determined as follows: 25 atomic % Ti, 24 atomic % Al, 50 atomic % N and 1 atomic % Cl. From these values and the values of the total layer thickness the thicknesses of the individual layers were determined at about 5 nm. With the aid of x-ray diffraction investigation, it was determined that the thin individual layers were present as discrete phases of titanium nitride and aluminum nitride and that they were continuous layers even at the submicroscope thicknesses. The hardness of the wear-protective coating of titanium nitride and aluminum nitride amounted to 3400 HV 0.05.

As the aforementioned examples show deposition of the individual layers while maintaining the temperature (≦750° C.) and the pressure in the framework of the present invention, makes a difference. With sufficiently rapid replacement of the gas atmosphere, the shutoff of the voltage for producing the glow discharge or the admission of a nonreactive gas with simultaneously pulsed direct current plasma excitation can be avoided.

The pulse direct current for producing the plasma is usually a rectangular voltage pulse with a maximum amplitude between 200 and 900 volts and a duration between 20 μs and 20 ms. Variations by the formation of nonvertical rising flanks and following flanks as well as inclined peaks are however also conceivable. The ratio of the pulse length (duration of the voltage signal of a pulse) to the period duration (pulse length plus pulse interval length) lies between 0.1 to 6.

1. A method of producing a wear-protective layer with a total thickness of 0.5 μm to 20 μm by a CVD process or a multiplicity of thin individual layers with a respective individual layer thickness of 1 to 100 nm, preferably 5 to 50 nm, in which on a substrate body the respective individual layers are deposited by varying the gas composition one after another, especially or producing a cutting insert coated with a wear-protective layer from a substrate body comprised of a hard metal, a cermet, a ceramic or a metal or a steel alloy, characterized by the use of a glow discharge plasma activated CVD process at a pressure of 50 Pa to 1000 Pa and a temperature of a maximum of 750° C. which during the change of the gas composition in preparation for the deposition of the next following individual layer, the voltage for producing the glow discharge is shut off.

2. The method for producing a hard protective layer has a total thickness of 0.5 μm to 20 μm by means of a CVD process from a multiplicity of thin individual layers with a respective individual layer thickness of 1 nm to 100 nm, preferably 5 nm to 50 nm in which the individual layers are successively deposited one after another on a substrate body, especially to produce a cutting insert comprised of a substrate body of a hard metal, cermet, a ceramic or a metal or a metal alloy coated with a wear-protective coating, characterized in that each of the individual layers is applied by means of a glow discharge plasma activated CVD process at a pressure of 50 Pa to 1000 Pa and a temperature of a maximum of 750° C. and between the individual coating processes for applying the individual layers with substantially constant high temperature a gas or gas mixture of argon, hydrogen and/or nitrogen is introduced at a pressure of 50 Pa to 1000 Pa into the coating vessel and a glow discharge is maintained on the substrate body or partially coated substrate body by the application of a voltage of 200 V to 1000 V for a duration which is shorter than the duration of the coating of the last individual layer, preferably a maximum of half as long.

3. The method according to claim 1, characterized in that at least two neighboring individual layers are comprised of hard materials which are not miscible with one another (alloyable) in thermal equilibrium.

4. The method according to claim 1, characterized in that the hard material from which the individual layers are comprised include at least two components of which the first contains at least one element of groups IVB to VIB of the periodic system or Al, Si, C, B and the second component is different and contains at least one element selected from the group of elements B, C, N, O and S.

5. The method according to claim 1, characterized in that at least a part of the wear-protective layer has individual layers in an alternating sequence of Al₂O₃, ZrO₂, AlN, BN or B(C,N) on the one hand and nitrides or carbonitrides of the form (Cₓ, N₁₋ₓ) with 0≦x≦1 of the elements Ti, Zr, Hf.

6. The method according to claim 1, characterized in that at least a part of the wear-protective layer includes an alternating sequence of individual layers deposited of TiN and Ti(C,N).

7. The method according to claim 1, characterized in that additionally at least one intermediate layer is deposited with a thickness of 5 to 50 nm which is comprised of at least one of the elements or compounds of at least two of the elements C, N, Mo, W, Ti, Al and/or contains ZrO₂, Si or B as a further phase.

8. The method according to claim 1, characterized in that at least two neighboring individual layers have the same composition.

9. The method according to one of claim 1, characterized in that two or more individual layers are deposited in a periodic repetitive sequence or nonperiodically.

10. A composite material, especially a tool, comprised of a substrate body composed of a hard metal, a cermet, a ceramic or a metal or a metal alloy and a wear-protective coating disposed thereon from a multiplicity of individual layers of a thickness between 1 to 100 nm, preferably 5 to 50 nm, characterized in that the individual layers are each deposited by means of a glow discharge plasma activated CVD process with a pressure of 50 Pa to 1000 Pa and a temperature of a maximum of 750° C., whereby between two coating processes in preparation in the deposition of the next individual layer either the voltage for producing the glow discharge is shut off or a gas or a gas mixture of argon, hydrogen and/or nitrogen is admitted to the coating vessel at a pressure of 10 Pa to 1000 Pa and the flow discharge on the substrate body or partly coated substrate body is maintained by applying a voltage of 200 V to 1000 V for a duration which is shorter than the duration of the coating of the last individual layer, preferably a maximum of half as long.

11. The composite material according to claim 10, characterized in that two or more successive individual layers each have different compositions.

12. The composite material according to claim 10, characterized in that at least two individual layers are of hard material.

13. The composite material according to claim 12, characterized in that the hard material contains at least one metal of groups IVB to VIB of the periodic system, Al, Si or B on the one hand and at least one of the elements, C, N, O and/or B on the other.

14. The composite material according to claim 10, characterized in that at least for a part of the individual layers following each other in alternate succession of the wear-protective layer are comprised of Al₂O₃, ZrO₂, AlN, BN or B(C,N) on the one hand and nitrides or carbonitrides of the form (Cₓ,N₁₋ₓ) with 0≦x≦1 of the elements Ti, Zr, Hf on the other hand.

15. The composite material according to claim 10, characterized in that at least for a part of the wear-protective layer is an alternating sequence of individual layers of TiN and Ti(C,N).

16. The composite material according to claim 10, characterized in that at least one hard material individual layer is comprised of a metal carbonitride compound or metal nitride compound of the composition (M₁,M₂) (Cₓ,N_{y}) whereby M₁ and M₂ are different metals and preferably from the group of Ti, Zr, Hf, V, Nb and Ta and 0≦x≦1 and 0≦y≦1.
